(19) United States
(12) Patent Application Publication
(10) Pub. No.: US 2017/0301382 A1
(43) Pub. Date: Oct. 19, 2017

(54) METHOD AND APPARATUS FOR SHARED MULTI-PORT MEMORY ACCESS

(71) Applicant: Cavium, Inc., San Jose, CA (US)

(72) Inventors: Jason Daniel Zebchuk, Watertown, MA (US); Gregg Alan Bouchard, Georgetown, TX (US); David Glen Roe, San Jose, CA (US)

(73) Assignee: Cavium, Inc., San Jose, CA (US)

(21) Appl. No.: 15/099,552

(22) Filed: Apr. 14, 2016

(51) Int. Cl. G11C 7/10; G06F 13/16

(52) U.S. Cl. CPC G11C 7/1075; G06F 13/1663

(57) ABSTRACT

Method and system embodying the method for a general address transformation for an access to a shared memory comprising at least one tile and each tile comprising at least one memory bank, comprising selecting a mode of a general address transformation; providing a general address comprising a plurality of bits by at least one of a plurality of devices; and transforming the general address onto a transformed address according to the selected mode; wherein in a first selected mode the transforming comprises determining each of a plurality of bits of a transformed address as an exclusive or of at least two bits of the plurality of bits of the general address provided that the shared memory comprises a plurality of tiles, and/or each tile comprises a plurality of banks is disclosed.

### BACKGROUND

### 1. Field

The present disclosure relates to shared multi-port memory access. More particularly, this invention is directed toward reducing contention and access time during access to shared multi-ported memory from multiple devices.

### 2. Description of Related Technology

In computer systems, a memory may be shared by a plurality of data processing devices. The shared memory may comprise one or more physical ports, enabling the plurality of devices access to the memory. When multiple of the plurality of the devices attempt to access the shared memory simultaneously, the access attempts may result in high contention, which requires serialization of the access attempts that increases average transaction latency and may reduce bandwidth utilization.

FIG. 1 depicts a conceptual structure 100 of a plurality of devices 102(D) accessing a shared memory 104 in accordance with known aspects. To mitigate the contention, the shared memory 104 may be internally divided into a plurality, e.g., four, memory banks 106(B). A memory bank is a physical unit of storage consisting of multiple rows and columns of storage units. An access, comprising a single read or write operation, uses only one bank and one physical port 108(P) at a time. The plurality of devices 102(D) are communicatively coupled to the physical ports 108(P) via a coupling device 110. The coupling device 110 enables any device 102(D) to be coupled to one or more physical ports 108(P). A person of ordinary skill in the art will understand that different number of memory banks, physical ports, is contemplated.

If two devices 102(D) simultaneously request access to different memory banks 106(B) over different physical ports 108(P), no contention occurs and the shared memory 104 may service the requests. In this case the full bandwidth is utilized. However, if two devices 102(D) simultaneously request access to different memory banks 106(B) over the same port 108(P), a shared memory contention occurs and the shared memory 104 cannot service the simultaneous requests; consequently, the requests are serialized and the shared memory 104 services the requests one at a time. Similarly, if two devices 102(D) simultaneously request access to the same memory bank 106(B) over different ports 108(P), a memory bank contention occurs, the access requests are serialized and the shared memory 104 services the requests. Regardless of the mechanism causing the contention, the need to serialize the simultaneous requests results in increased average transaction latency, and may reduce bandwidth utilization.

One approach to further improving bandwidth utilization, is to increase the plurality of physical ports, and/or arrange the shared memory into a plurality of tiles. A shared memory is partitioned into a plurality of memories, i.e., memory tiles. However, increasing number of ports and/or memory tiles is limited due to increased complexity, area, and power requirements.

Accordingly, there is a need in the art for a method and an apparatus implementing the method for reducing contention and access time during accessing shared multi-ported memory by multiple devices, as well as additional advantages.

### SUMMARY

In an aspect of the disclosure, an apparatus implementing a method for address transformation for an access to a shared memory comprising at least one tile, each tile comprising at least one memory bank according to appended independent claims is disclosed. Additional aspects are disclosed in the dependent claims.

### BRIEF DESCRIPTION OF THE DRAWINGS

The foregoing aspects described herein will become more readily apparent by reference to the following description when taken in conjunction with the accompanying drawings wherein:

FIG. 1 depicts a conceptual structure 100 of a plurality of devices simultaneously accessing a shared memory in accordance with known aspects;

FIG. 2 depicts a conceptual structure 200 for reducing contention and access time during simultaneous access of a shared multi-ported memory by multiple devices in accordance with aspects of this disclosure;

FIG. 3a depicts a conceptual structure 300 of transforming a general address into a transformed address in accordance with one aspect of this disclosure;

FIG. 3b depicts a conceptual structure 300 of transforming a general address into a transformed address in accordance with another aspect of this disclosure;

FIG. 3c depicts a conceptual structure 300 of transforming a general address into a transformed address in accordance with another aspect of this disclosure;

FIG. 4. depicts a conceptual structure 400 of transforming a general address into a transformed address in accordance with another aspect of this disclosure; and

FIG. 5 depicts a flow chart for a process for address transformation for an access to a shared memory comprising at least one tile, each tile comprising at least one memory bank in accordance with the concepts of this disclosure.

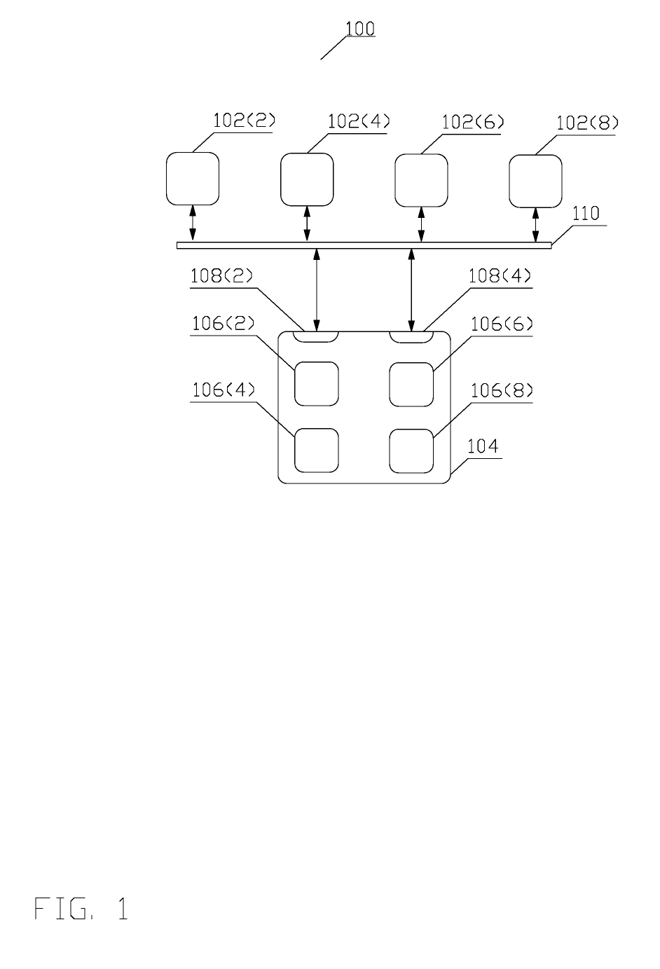

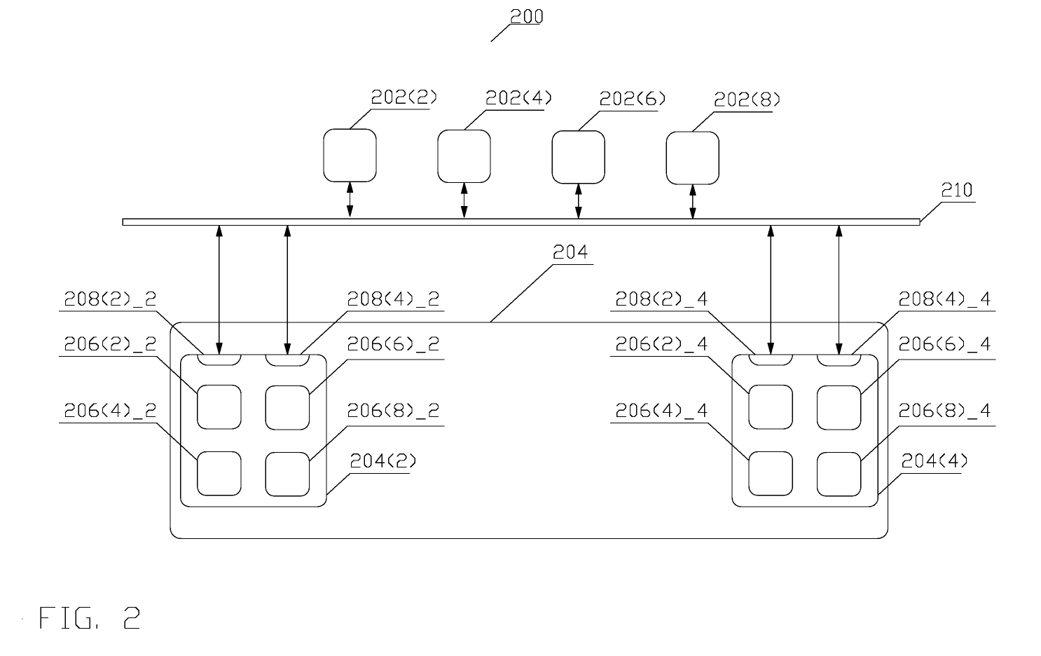

The description of like structural elements among the figures, is not repeated, the like elements have reference numerals differing by an integer multiple of 100, i.e., reference numeral 102 in FIG. 1, becomes reference numeral 202 in FIG. 2; unless differences and/or alternative aspects are explicitly noted. In the drawings, an expression “_X” in a reference indicates an instance of an element, while and expression “(X)” indicates a sub-block in a drawing where helpful for better understanding. Any unreferenced single and/or double-arrow line indicates a possible information flow between the depicted entities.

Additionally, to further clarify the relationship between certain elements in different figures, references of elements in figures not currently described are in parenthesis.

### DETAILED DESCRIPTION

Unless otherwise defined, all terms (including technical and scientific terms) used herein have the same meaning as commonly understood by a person having ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The term “communicatively coupled” is intended to specify a communication path permitting information exchange either directly among the communicatively coupled entities, or via an intervening entity.

Various disclosed aspects may be illustrated with reference to one or more exemplary configurations. As used herein, the term “exemplary” means “serving as an example, instance, or illustration,” and should not necessarily be construed as preferred or advantageous over other configurations disclosed herein.

Various aspects of the present invention will be described herein with reference to drawings that are schematic illustrations of conceptual configurations of the present invention, unless explicitly noted. The various aspects of this disclosure are provided to enable a person having ordinary skill in the art to practice the present invention. Modifications to various aspects presented throughout this disclosure will be readily apparent to a person having ordinary skill in the art, and the concepts disclosed herein may be extended to other applications.

FIG. 2 depicts a conceptual structure 200 for reducing contention and access time during simultaneous access of a shared multi-ported memory by multiple devices in accordance with aspects of this disclosure. The shared memory 204 comprises a plurality of distinct tiles 204(T). Each of the tiles 204(T) is internally divided into a plurality of memory banks 206(B). In one aspect, each memory bank 206(B) comprises a single-port random-access memory (RAM), to provide the most optimal RAM density per unit area. In a single read or write operation, only one memory bank 206(B) per a physical port 208(P) may be accessed at the same time; however, each tile 204(T) may simultaneously service a plurality of requests, one request per physical port 208(P) to a different memory bank 206(B) at the same time. To enable access to each of the plurality of memory banks 206(B) in a tile 204(T), each physical port 208(P) of the tile 204(T) comprises a structure (not shown) transforming at least a portion of an address received at the physical port 208(P) to a memory bank 206(B). A plurality of devices 202(D) are communicatively coupled to a plurality of physical ports 208(P) via a coupling device 210. Such a device may comprise any hardware or a software entity executing on an underlying hardware, carrying out processing utilizing the memory. The coupling device 210 enables any device 202(D) to be coupled to any physical port 208(P) such that any device 202(D) may access the entire shared memory 204 space. Although a shared memory 204 comprising T=2 tiles, each tile comprising B=4 memory banks, and P=2 physical ports, and D=4 devices are shown, a person of ordinary skill in the art will understand that such is for exemplary purposes only, and different number of tiles, memory banks, physical ports, and devices is contemplated.

In one aspect, the coupling device 210 comprises a plurality of high speed buffered crossbar switches, organized as an m×n matrix to connect m input ports to n output ports. The number of input ports m is equal to the number of the plurality of devices 202(D); the number of output ports n is equal to the number of the plurality of tiles 204(T). Consequently, the number of the plurality of high speed buffered crossbar switches is equal to the plurality of physical ports 208(P). The high speed buffered crossbar switches can transfer packets from multiple input ports to multiple outputs simultaneously. Each pair of input and output ports has a dedicated path through the switch, and additional ports can be incorporated by adding switching elements.

Assuming, without any loss of generality, that each memory bank 204 bank contains 2^{N} bytes of data, to address every byte of data, a general address represented as a binary number of size log₂ (T+B)+N bits is needed. The general address is generated by a device (202(D)). Since the device (202(D)) does not have any notion about the organization of the data in the shared memory 204, the general address must be transformed onto a transformed address.

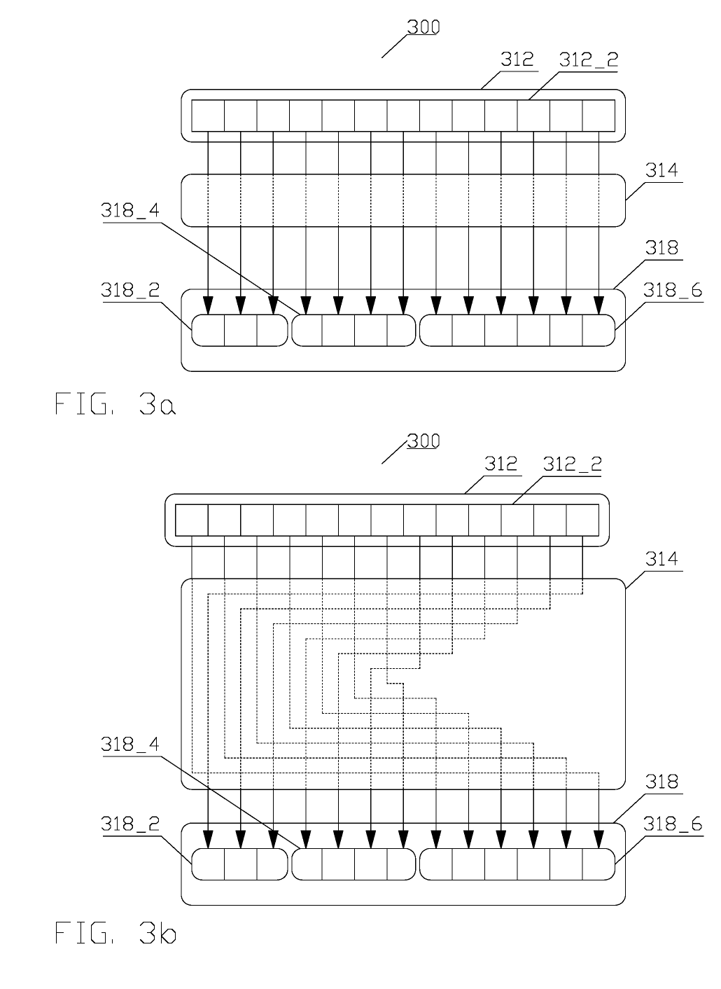

FIG. 3a depicts a conceptual structure 300 of an address transformation in accordance with one aspect. The general address 312 is provided by one of the plurality of devices (not shown) to a transformation block 314. The transformation block 314 may be implemented as a part of the device (202(D)), as a part of the coupling device (210), or a hardware or a software entity executing on the hardware implementing the conceptual structure (200). According to this aspect, simple addressing is used. The transformation block 314 transforms bits from the general address 312 onto the transformed address 318 in the order of the bits significance; consequently, a tile index 318_2, identifying a tile (204(T)) to be accessed comprises the most significant log₂ (T) bits of the general address 312, the bank index 318_4, identifying a memory bank (206(B)) to be accessed comprises the next (mid) significant log₂ (B) bits of the general address 312, and the offset 318_6 identifying the byte to be accessed, comprised the least significant N bits of the general address 312.

In case of address transformation according to the above-disclosed aspect, a sequence of consecutive general addresses 312 will be mapped to increasing offsets within a tile (204(T)) to one or more memory banks (206(B)). Contention shall occur when two or more devices (202(D)) use the same physical port (208(P)) to simultaneously access the same memory bank (206(B)) even though the access may be to different sequences. Additionally, contention shall occur when two or more devices (202(D)) use different physical port (208(P)) to simultaneously access the same memory bank (206(B)) even though the access may be to different sequences. In both cases, all simultaneous access to the sequences will cause contention

Contention may occur when two or more devices (202(D)) use the same physical port (208(P)) to simultaneously access different sequences that partially reside within the same tile (204(T)). Additionally, contention may occur when two or more devices (202(D)) use different physical port (208(P)) to simultaneously access different sequences that partially reside within the same memory bank (206(B)). In other words, contention will occur if and only if the simultaneous accesses from the different devices (202(D)) simultaneously access the portion of the respective sequences that reside within the same tile (204(T)) or memory bank (206(B)). In all other cases contention will not occur.

Similarly, in the case of stride access, the sequence of addresses 300 separated by a constant stride will be transformed to increasing offsets within a tile (204(T)) to one or more memory banks (206(B)). Consequently, the contention patterns as disclosed in the case of sequential addressing will occur. In addition, when two or more devices (202(D)) use different physical port (208(P)) to simultaneously access different sequences with the same constant stride, and when the stride is a multiple of 2^{N}, then if memory bank (206(B)) contention occurs for two simultaneous accesses, then it will re-occur for subsequent simultaneous accesses.

Despite a possibility of contention, the addressing disclosed supra allows easy prediction of tile and memory bank contention. This predictability enables design of an allocation of data structures among tiles and memory banks, so that specific cases of processing will have a limited or no number of predictable tile and memory bank contention. This predictability enables ensuring that the resulting bandwidth and average access latency meet the requirements of the specific case of processing. By means of an example, consider a scenario wherein the plurality of devices (202(D)) access different data structures at different times. A careful design of allocation of the data structures may result in zero bank or tile conflicts for such a scenario; consequently, the addressing guarantees a specific runtime bandwidth and average access latency. Such a scenario may be encountered in, e.g., processing of a physical layer of antenna data for a plurality of antennas with a known configuration in a Long Term Evolution (LTE) communication system.

In addition, sequential addressing allows software designer to exploit the fact that large blocks of memory map uniformly.

FIGS. 3b-c depict a conceptual structure 300 of an address in accordance with other aspect. According to this aspect, interleaved addressing is used. The general address 312 is provided by one of the plurality of devices (not shown) to a transformation block 314.

By means of an example of interleaved addressing depicted in FIG. 3b, the transformation block 314 transforms bits from the general address 312 onto the transformed address 318 in a reverse order of the bits significance; consequently, the least-significant general address 312 bits select the tile (204(T)), the next (mid) significant bits select the memory bank (206(B)), and the most significant bits select the offset within the memory bank (206(B)). Thus, the first alternative of the interleaved addressing is a reverse of simple addressing.

By means of another example of interleaved addressing depicted in FIG. 3c, the transformation block 314 transforms bits from the general address 312 onto the transformed address 318 by first reversing the order of the bits significance and then reversing the order of the bits within the indices, i.e., the tile index 318_2, the memory bank index 318_4, and the offset index 318_6. However, just like first alternative, the least-significant general address 312 bits select the tile (204(T)), the next (mid) significant bits select the memory bank (206(B)), and the most significant bits select the offset within the memory bank (206(B)).

A person of ordinary skill in the art will understand that the examples of the interleaved addressing are provided only for explaining the concepts; consequently, other examples of interleaved addressing are contemplated, where, in general, an interleaved address transformation consists of a permutation of the general address bits.

The transformation creates a pseudo-random mapping between the general address 312 and the tiles (204(T)) and the memory bank (206(B)) indices. The interleaved addressing thus spreads a sequence of consecutive general addresses 312 across tiles (204(T)) and across memory banks (206(B)) within the tiles (204(T)), significantly reducing contention in comparison to the simple addressing. However, in case of constant stride being a multiple of the number of tiles (204(T)), if any conflict occurs at the tile (204(T)), the entire sequences will have conflicts at the tile (204(T)). Similarly, in the case of stride access, when the stride is a multiple of 2^{(B+T)}, then if any conflict occurs at a memory bank (206(B)), the entire sequences will have conflicts at the memory bank (206(B)). In addition, the interleaved addressing is more difficult to analyze; therefore, complicating attempts to allocate data structures so as to avoid conflicts.

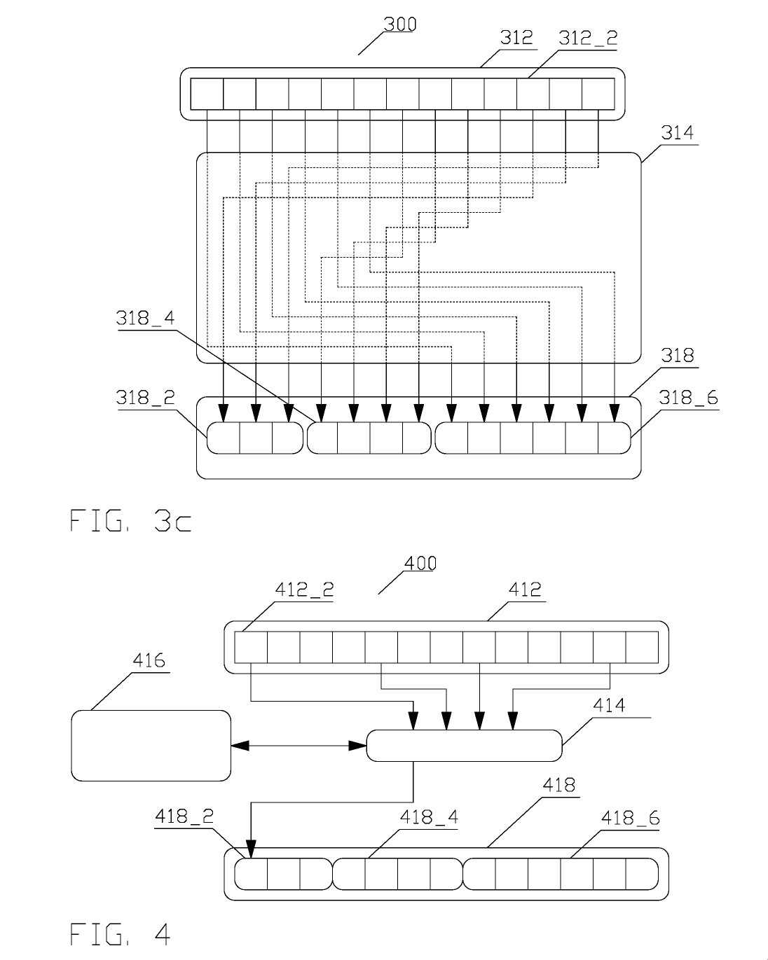

FIG. 4. depicts a conceptual structure 400 of an address transformation in accordance with yet another aspect. The general address 412 is provided by one of the plurality of devices (not shown). The transformation block 414 may be implemented as a part of the device (202(D)), as a part of the coupling device (210), or a hardware or a software entity executing on the hardware implementing the conceptual structure (200). The transformation block 414 looks up exponents of transformation polynomial variable in a look-up table 416, according to the bit position to be calculated for the transformed address 418. As depicted the most significant bit of the tile index 418_2 is to be calculated. The polynomial, given by an equation:

t₀=x¹³+x⁹+x⁶+1 Eq. 1

determines which bits of the general address 412 are used for the calculation. The bits are determined by the exponent of the polynomial's variable. Thus, as depicted, bits at the positions 0, 6, 9, and 13 are used for the calculation. The transformation block 414 carries an exclusive or (XOR) logical operation on the bits at the positions 0, 6, 9, and 13 and outputs the resulting value into the most significant bit of the tile index 418_2 of the transformed address 418. The process is repeated for all the remaining bits of the transformed address 418, wherein each of the remaining bits is determined by a different polynomial stored in the look-up table 416.

In another aspect, instead of a sequential transformed address 418 bit calculation, the bits may be calculated in parallel. Thus, the transformation block 414 may comprise a plurality of sub-blocks (not shown) each sub-block calculating bit for a different position in the transformed address 418, by having the sub-block inputs hardwired to the bit position of the general address 412 determined by exponents of variable of an associated polynomial. Consequently, no look-up table 416 is required.

When designing the polynomials, two necessary conditions are that for each bit in the general address 412, there exists a corresponding polynomial, and that the designed polynomials are linearly independent to assure one-to-one transformation between the general address 412 and the transformed address 418. To avoid contention, additional criterion needs to ensure that a set of consecutive memory addresses map to different tiles (204(T)) and/or memory banks (206(B)), consequently, the polynomials need to include at least one of the most significant log₂ (T) bits from the general address 412 and/or at least one of the mid significant log₂ (B) bits of the general address 412. Consequently, when the plurality of the devices (202(D)) simultaneously access a sequence of consecutive general addresses 412, the simultaneous accesses are unlikely to produce a repeating series of tiles (204(T)) and/or memory banks (206(B)) conflicts because each sequence will likely alternate between tiles (204(T)) and/or memory banks 206(B)) in a different order.

Additionally, a knowledge of a specific application may introduce additional design criteria. By means of an example, consider that the plurality of the devices 202(D) is to be used for baseband signal processing of an LTE communication system. A typical baseband processing data structure comprises a two-dimensional array of n-bit values, where one dimension is a number of sub-carriers and the other dimension is the number of symbols in a sub-frame. Some processing algorithm may sequentially stride through subcarriers within an individual symbol, other processing algorithm may stride between symbols, and yet other algorithms might combine these two patterns to sequentially stride through a subset of carriers within a symbol and then stride through the same subcarriers for each subsequent symbol.

These algorithms imply the use of sequential accesses and a specific stride offset—the number of subcarriers per symbol. Therefore, the polynomials may be optimized by combining at least one low-order bit with at least one middle bit from the general address 412, where the middle bit is selected based on the base 2 logarithm of the number of subcarriers per symbol (N_{sc}) times the number of bytes per entry in the data structure (b_{sc}). Thus, when:

[log₂(N_{sc}×b_{sc})]≦i≦[log₂(N_{sc}×b_{sc})] Eq. 2

then the polynomials might include bits i, i+1, and i+2.

In other words, the data structure implies two different stride offsets; therefore, the polynomials may be optimized for these different stride offsets by combining bits from the general address 412 near the base 2 logarithm of the stride offset.

Following the necessary conditions and design criteria supra, it is possible to design different sets of polynomials for different processing data structure, which would then be used for processing the data structure. By means of an example, a set of polynomials could be used for processing of a data structure for single antenna mode for LTE communication system and a different set of polynomials could be used for processing of a data structure for multiple-input-multiple-output mode of LTE communication system.

It is understood, that different sizes of the shared memory 202 and/or different number of the plurality of the tiles 204(T) and/or different number of the plurality of the memory banks 202_B in each tile 201_T, require a different size of the general address 312, 412 and, consequently a different number of the polynomials. By means of an example, in one aspect, the size of the shared memory 204 is 8 mega bytes (MB), consisting of 8 tiles 204(T) of size 1 MB, internally divided into 64 memory banks 206(B), each containing 16 kilo bytes (kB) of data. Using the above-disclosed design criteria, the polynomials for calculating the XOR function are given by the following equations:

t₀=x²⁰+x¹²+x⁹+x⁴ Eq. 3

t₁=x²¹+x¹³+x¹⁰+x⁵ Eq. 4

t₂=x²²+x¹⁴+x¹¹+x⁶ Eq. 5

wherein t₀, t₁, and t₂ comprise the 3-bit tile index of the transformed address;

b₀=x²²+x¹⁹+x¹³+x¹⁰+x⁴ Eq. 6

b₁=x²⁰+x¹⁴+x¹¹+x⁵ Eq. 8

b₂=x²¹+x¹⁵+x¹²+x⁶ Eq. 9

b₃=x¹⁹+x¹⁶+x¹⁰+x⁷ Eq. 10

b₄=x²⁰+x¹⁹+x¹¹+x⁸ Eq. 11

b₅=x²¹+x¹⁸+x¹²+x⁹ Eq. 12

wherein b₀, b₁, b₂, b₃, b₄, and b₅ comprise the 6-bit memory bank index of the transformed address; and

nᵢ=xⁱ, for i=0, . . . ,3 Eq. 13

nᵢ=x⁽⁹⁺ⁱ⁾, for i=4, . . . ,13 Eq. 14

wherein n₀ through n₁₃ comprise the 13-bit offset index of the transformed address.

Person of ordinary skill in the art will appreciate that the order of the tile index 318_2, 418_2, the memory bank index 318_4, 418_4, and the offset index 318_6, 418_6, depicted in FIG. 3-FIG. 4 is for the explanation of the concept of the transformation. The order of the indices 318_2, 418_2, 318_4, 418_4, and 318_6, 418_6 and the design of a corresponding transformation blocks 314, 414 depends on the design of the interface between the devices (202(D)) and the shared memory 202.

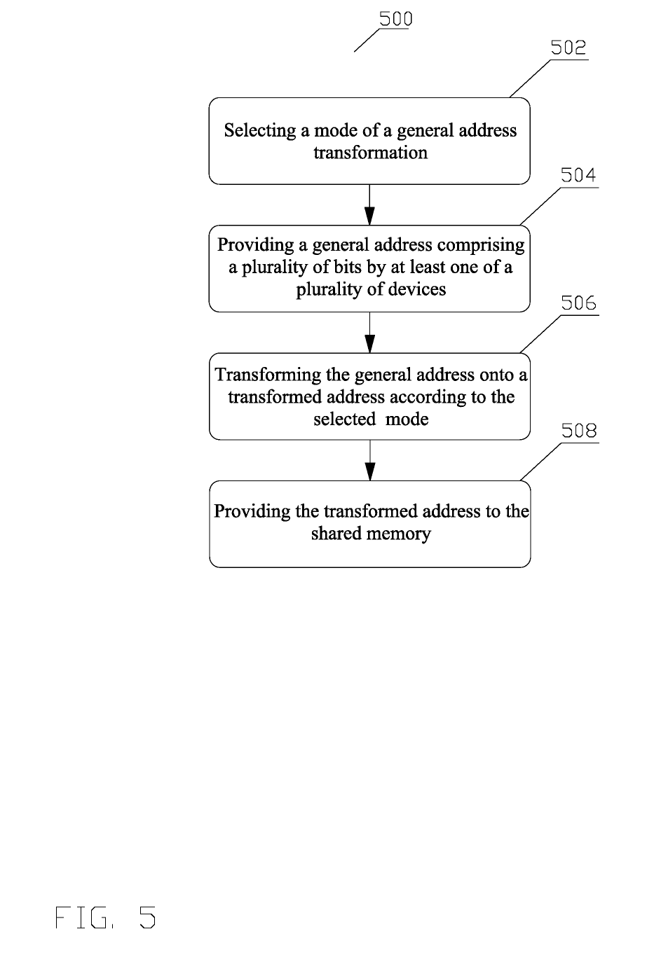

FIG. 5 depicts a flow chart for a process for address transformation for an access to a shared memory comprising at least one tile, each tile comprising at least one memory bank in accordance with the concepts of this disclosure.

In block 502, a controller entity selects a mode of the general address transformation. Such an entity may comprise any hardware controller or a software controller executing on the hardware implementing the conceptual structure (200). As disclosed supra, the mode of the general address transformation may comprise a simple address translation, an interleaved address translation, and an address translation based on XOR of bits identified by exponents of transformation polynomial(s). The process continues in block 504.

In block 504, at least one of the plurality of devices (202(D)) generates a general address comprising a plurality of bits, and provides the general address to a transformation block (314), (414). The process continues in block 506.

In block 506, the transformation block (314), (414) transforms the general address onto a transformed address according to the selected mode. The address transformation is thus completed and the transformed address may then be provided to the shared memory as shown in block 508.

The various aspects of this disclosure are provided to enable a person having ordinary skill in the art to practice the present invention. Various modifications to these aspects will be readily apparent to persons of ordinary skill in the art, and the concepts disclosed therein may be applied to other aspects without departing from the spirit or scope of the invention. Thus, the present invention is not intended to be limited to the aspects shown herein but is to be accorded the widest scope consistent with the principles and novel features disclosed herein.

Therefore, by means of an example a person having ordinary skill in the art will understand, that the flow chart is not exhaustive because certain blocks may be added or be unnecessary and/or may be carried out in different sequence or in parallel based on a particular implementation. By means of an example, the sequence of operations of blocks 502 and 504 may be exchanged or the operations may be carried out in parallel.

All structural and functional equivalents to the various illustrative logical blocks, modules, circuits, and algorithm steps described in connection with the various aspects described throughout this disclosure that are known or later come to be known to those of ordinary skill in the art are expressly incorporated herein by reference and are intended to be encompassed by the claims. Such illustrative logical blocks, modules, circuits, and algorithm steps may be implemented as electronic hardware, computer software, or combinations of both.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A method for a general address transformation for an access to a shared memory comprising at least one tile and each tile comprising at least one memory bank, the method comprising:
selecting a mode of a general address transformation;
providing a general address comprising a plurality of bits by at least one of a plurality of devices; and
transforming the general address onto a transformed address according to the selected mode; wherein
in a first selected mode the transforming comprises determining each of a plurality of bits of a transformed address as an exclusive or of at least two bits of the plurality of bits of the general address provided that the shared memory comprises a plurality of tiles, and/or each tile comprises a plurality of banks.

2. The method as claimed in claim 1, wherein the determining each of a plurality of bits of a transformed address as an exclusive or of at least two bits of the plurality of bits of the general address provided that the shared memory comprises a plurality of tiles, and/or each tile comprises a plurality of banks comprises:
determining each of at least one tile index bit of a transformed address as the exclusive or of at least one of most significant bits and at least one of least significant bits of the plurality of bits of the general address provided that the shared memory comprises a plurality of tiles.

3. The method as claimed in claim 2, further comprising:
determining each of at least one bank index bit of a translated address as the exclusive or of the most significant bits and at least one of the least significant bits of the plurality of bits of the general address provided that the shared memory comprises a plurality of banks.

4. The method as claimed in claim 1, wherein the determining each of a plurality of bits of a transformed address as an exclusive or of at least two bits of the plurality of bits of the general address provided that the shared memory comprises a plurality of tiles, and/or each tile comprises a plurality of banks comprises:
determining the at least two bits of the plurality of the bits of the general address according to an exponent of at least one polynomial.

5. The method as claimed in claim 4, wherein
the shared memory comprises eight tiles, each tile comprising sixty-four memory banks; and
the at least one polynomial comprises a plurality of polynomials given by the following equations:
t₀=x²⁰+x¹²+x⁹+x⁴
t₁=x²¹+x¹³+x¹⁰+x⁵
t₂=x²²+x¹⁴+x¹¹+x⁶
b₀=x²²+x¹⁹+x¹³+x¹⁰+x⁴
b₁=x²⁰+x¹⁴+x¹¹+x⁵
b₂=x²¹+x¹⁵+x¹²+x⁶
b₃=x¹⁹+x¹⁶+x¹⁰+x⁷
b₄=x²⁰+x¹⁹+x¹¹+x⁸
b₅=x²¹+x¹⁸+x¹²+x⁹
nᵢ=xⁱ, for i=0, . . . ,3
nᵢ=x⁽⁹⁺ⁱ⁾, for i=4, . . . ,13; and
wherein, t₀, t₁, and t₂ comprise the tile index, b₀, b₁, b₂, b₃, b₄, and b₅ comprise the memory bank index, and n₀ through n₁₃ comprise an offset index of the transformed address.

6. The method as claimed in claim 1, wherein in a second selected mode the transforming comprises:
mapping the plurality of bits from the general address onto the plurality of bits of the transformed address in the order of the bits significance.

7. The method as claimed in claim 1, wherein in a third selected mode the transforming comprises:
mapping the plurality of bits from the general address onto the plurality of bits of the transformed address according to interleaved addressing.

8. The method as claimed in claim 7, wherein the interleaved addressing maps the plurality of bits from the general address onto the plurality of bits of the transformed address according to a reverse order of the bits significance.

9. The method as claimed in claim 7, wherein the interleaved addressing maps the plurality of bits from the general address onto the plurality of bits of the transformed address according to a reverse order of a tile index, a bank index, and a bank offset index while maintaining the order of bits significance within the tile index, the bank index, and the bank offset index.

10. An apparatus for address transformation for an access to a shared memory comprising at least one tile, each tile comprising at least one memory bank, the apparatus comprising:
a controller configured to select a mode of a general address transformation;
a plurality of devices, at least one of the plurality of devices providing a general address comprising a plurality of bits providing; and
a transformation block configured to transform the general address onto a transformed address according to the selected mode; wherein
in a first selected mode the transformation block determines each of a plurality of bits of a transformed address as an exclusive or of at least two bits of the plurality of bits of the general address provided that the shared memory comprises a plurality of tiles, and/or each tile comprises a plurality of banks.

11. The apparatus as claimed in claim 10, wherein the transformation block the determines each of a plurality of bits of a transformed address as an exclusive or of at least two bits of the plurality of bits of the general address provided that the shared memory comprises a plurality of tiles, and/or each tile comprises a plurality of banks by being configured to:
determine each of at least one tile index bit of a transformed address as the exclusive or of at least one of most significant bits and at least one of least significant bits of the plurality of bits of the general address provided that the shared memory comprises a plurality of tiles.

12. The apparatus as claimed in claim 11, wherein the transformation block is further configured to:
determine each of at least one bank index bit of a translated address as the exclusive or of the most significant bits and at least one of the least significant bits of the plurality of bits of the general address provided that the shared memory comprises a plurality of banks.

13. The apparatus as claimed in claim 10, wherein the transformation block determines each of a plurality of bits of a transformed address as an exclusive or of at least two bits of the plurality of bits of the general address provided that the shared memory comprises a plurality of tiles, and/or each tile comprises a plurality of banks by being configured to:
determine the at least two bits of the plurality of the bits of the general address according to an exponent of at least one polynomial.

14. The apparatus as claimed in claim 13, wherein
the shared memory comprises eight tiles, each tile comprising sixty-four of memory banks; and
the at least one polynomial comprises a plurality of polynomials given by the following equations:
t₀=x²⁰+x¹²+x⁹+x⁴
tᵢ=x²¹+x¹³+x¹⁰+x⁵
t₂=x²²+x¹⁴+x¹¹+x⁶
b₀=x²²+x¹⁹+x¹³+x¹⁰+x⁴
b₁=x²⁰+x¹⁴+x¹¹+x⁵
b₂=x²¹+x¹⁵+x¹²+x⁶
b₃=x¹⁹+x¹⁶+x¹⁰+x⁷
b₄=x²⁰+x¹⁹+x¹¹+x⁸
b₅=x²¹+x¹⁸+x¹²+x⁹
nᵢ=xⁱ, for i=0, . . . ,3
nᵢ=x⁽⁹⁺ⁱ⁾, for i=4, . . . ,13; and
wherein, t₀, t₁, and t₂ comprise the tile index, b₀, b₁, b₂, b₃, b₄, and b₅ comprise the memory bank index, and n₀ through n₁₃ comprise an offset index of the transformed address.

15. The apparatus as claimed in claim 10, wherein in a second selected mode the transformation block is configured to:
map the plurality of bits from the general address onto the plurality of bits of the transformed address in the order of the bits significance.

16. The apparatus as claimed in claim 10, wherein in a third selected mode the transformation block is configured to:
map the plurality of bits from the general address onto the plurality of bits of the transformed address according to interleaved addressing.

17. The apparatus as claimed in claim 16, wherein the transformation block maps the plurality of bits from the general address onto the plurality of bits of the transformed address according to interleaved addressing by being configured to:
map the plurality of bits from the general address onto the plurality of bits of the transformed address according to a reverse order of the bits significance.

18. The apparatus as claimed in claim 16, wherein the transformation block maps the plurality of bits from the general address onto the plurality of bits of the transformed address according to interleaved addressing by being configured to:
map the plurality of bits from the general address onto the plurality of bits of the transformed address according to a reverse order of a tile index, a bank index, and a bank offset index, while maintaining the order of bits significance within the tile index, the bank index, and the bank offset index.

19. A non-transitory computer readable medium storing one or more instructions executing on an electronic hardware causes the hardware to carry out a method comprising:
selecting a mode of a general address transformation;
providing a general address comprising a plurality of bits by at least one of a plurality of devices; and
transforming the general address onto a transformed address according to the selected mode; wherein
in a first selected mode the transforming comprises determining each of a plurality of bits of a transformed address as an exclusive or of at least two bits of the plurality of bits of the general address provided that the shared memory comprises a plurality of tiles, and/or each tile comprises a plurality of banks.
